(19) United States
(12) Patent Application Publication
(10) Pub. No.: US 2007/0158838 A1
(43) Pub. Date: Jul. 12, 2007

(54) Circuit board, method for manufacturing the same, semiconductor device, and method for manufacturing the same

(75) Inventor: Toshio Fujii, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/649,870

(22) Filed: Jan. 5, 2007

(30) Foreign Application Priority Data
Jan. 6, 2006 (JP) 2006-000977

(51) Int. Cl. H01L 21/00; H01L 23/48

(52) U.S. Cl. 257/734; 29/25.01

(57) ABSTRACT

A circuit board for flip-chip packaging is provided which can achieve the connection reliability of a semiconductor device and the circuit board. The circuit board for flip-chip packaging includes, on a surface of a substrate (6), wiring patterns (1), connection pads (2) for flip-chip packaging, and a solder resist (3) having openings (4) formed on the connection pads (2). In the circuit board, conductive members (5) are formed in the openings (4).

### FIELD OF THE INVENTION

The present invention relates to a circuit board for flip-chip packaging of a solder bonding method and a method for manufacturing the same, and relates to a semiconductor device in which a semiconductor chip is packaged by a flip-chip packaging technique and a method for manufacturing the same.

### BACKGROUND OF THE INVENTION

In recent years, as electronic equipment such as portable information equipment has been reduced in size, thickness, and weight, semiconductor devices (semiconductor packages) with higher densities and higher performance have been demanded. At the same time, as semiconductor chips have been improved in performance, the number of pins has considerably grown in the semiconductor chips. Further, the operating frequencies of semiconductor chips have increased simultaneously. In response to these needs, there have been developed semiconductor devices in which semiconductor chips are packaged by flip-chip packaging techniques.

In the flip-chip packaging techniques, the pads (electrodes) of a semiconductor chip are electrically connected face-down to the connection pads (main electrodes) of a circuit board. These techniques can minimize the footprint. Moreover, these techniques make it possible to connect a semiconductor chip and a circuit board with the shortest distance, thereby achieving a semiconductor device with excellent electrical characteristics such as a high-frequency characteristic.

At present, various kinds of flip-chip packaging techniques have been proposed. These techniques have been devised in terms of productivity and cost and are broadly classified into contact bonding and metal bonding.

In contact bonding, electrical bonding between the pads of a semiconductor chip and the connection pads of a circuit board is obtained by contact. Thus contact bonding has a high connection resistance. However, contact bonding can be easily applied to various substrate materials and is an environment-friendly bonding method.

Metal bonding is mainly typified by solder bonding. Metal bonding has a low connection resistance and can achieve a reliable semiconductor device.

A conventional flip-chip packaging technique of solder bonding will be specifically described below.

First, a circuit board is prepared which includes connection pads (main electrodes), wires, and a solder resist on one surface of a substrate. The solder resist covers the substrate surface where the connection pads and the wires are formed, so that the wires are protected.

Next, on the circuit board, the openings of the solder resist are formed on the connection pads by a patterning method (photolithography) using exposure and development.

When forming the openings of the solder resist by the patterning method using exposure and development, in consideration of a displacement of the position of the formed opening relative to the connection pad, an amount of overlap is set in the stage of design and the opening is reduced in size from the connection pad according to the amount of overlap. The amount of overlap is obtained as follows: the dimension of the opening of the solder resist is subtracted from the dimension of the connection pad (circular portion), and the obtained value is divided by 2.

While the openings of the solder resist are formed thus, solder bumps are formed on the pads of a semiconductor chip.

Next, the semiconductor chip is flipped over and caused to face the circuit board, the connection pads of the circuit board and the solder bumps of the semiconductor chip are aligned with each other, and the semiconductor chip is mounted on the circuit board.

After that, heat is applied to melt solder, so that the pads of the semiconductor chip and the connection pads of the circuit board are electrically connected to each other.

Further, underfil is dispensed into a gap between the semiconductor chip and the circuit board and cured in the gap.

A semiconductor device is obtained thus.

In this case, in order to obtain an electrical connection by melting solder, it is desirable to bring the solder bumps of the semiconductor chip and the connection pads of the circuit board into contact with each other when the semiconductor chip is mounted. Thus the opening of the solder resist has to have a sufficient diameter relative to the size of the bump.

However, in recent years, semiconductor chips and circuit boards have had finer patterns with higher densities and connection pads have been reduced in size in response to demand for smaller, thinner, and lighter electronic equipment. For this reason, when the opening of the solder resist is reduced in size from the connection pad by the amount of overlap as described above, the opening of the solder resist cannot have a sufficient diameter.

In response to this problem, for example, it has been proposed that the opening of a solder resist be precisely formed by laser radiation (Japanese Patent Laid-Open No. 2001-237338). When the opening of the solder resist is formed thus by laser radiation, the displacement of the opening of the solder resist can be reduced relative to a connection pad. Thus a small amount of overlap can be set and the opening of the solder resist can have a sufficient diameter. However, as compared with the method for forming the opening of the solder resist by the patterning method using exposure and development, the method for forming the opening of the solder resist by laser radiation has low productivity, thereby increasing the cost.

In the patterning method using exposure and development, a small amount of overlap can be set by increasing the accuracy of alignment but the cost increases.

The size of the bump may be set small in consideration of the diameter of the opening of the solder resist. However, as the bump is reduced in size, the bonding height decreases. Thus a gap between the semiconductor chip and the circuit board becomes smaller. Therefore, the filling property of underfil deteriorates and the yield, connection reliability, and so on of the semiconductor device decrease.

### DISCLOSURE OF THE INVENTION

In view of these problems, an object of the present invention is to provide a circuit board, a method for manufacturing the same, a semiconductor device, and a method for manufacturing the same that can contribute to the provision of a semiconductor device with high yield and connection reliability.

In order to attain the object, the circuit board of the present invention comprises a substrate, at least one wire formed on one surface of the substrate, a plurality of main electrodes formed on the one surface of the substrate, a solder resist covering the one surface of the substrate having the wire and the main electrodes formed thereon, the solder resist including openings on the main electrodes, and a conductive member formed in the opening and electrically connected to the main electrode.

According to the circuit board of the present invention, h−r+{r²−(w/2)²}^{1/2}≦x is satisfied where x represents the thickness of the conductive member, w represents the diameter of the opening, h represents the thickness of the solder resist, and r represents the radius of a solder bump formed on the electrode of a semiconductor chip mounted on the circuit board.

According to the circuit board of the present invention, the wire is disposed between the main electrodes.

According to the circuit board of the present invention, the conductive member contains at least one material selected from the group consisting of gold (Au), silver (Ag), copper (Cu), tin (Sn), indium (In), lead (Pb), bismuth (Bi), zinc (Zn), nickel (Ni), antimony (Sb), platinum (Pt), and palladium (Pd).

The circuit board of the present invention further comprises a second electrode electrically connected to the conductive member on the same surface as the solder resist.

According to the circuit board of the present invention, the second electrode is larger in diameter than the opening.

According to the circuit board of the present invention, the second electrode is larger in diameter than the main electrode.

The circuit board of the present invention further comprises a partition wall between the second electrodes, the partition wall being larger in thickness than the second electrode.

According to the circuit board of the present invention, the partition wall covers the outer periphery of the second electrode.

A method for manufacturing a circuit board of the present invention comprises: preparing the circuit board including, on one surface of a substrate, at least one wire, a plurality of main electrodes, and a solder resist covering the one surface of the substrate having the wire and the main electrodes formed thereon, forming the openings of the solder resist on the main electrodes, and forming a conductive member in each of the openings.

According to the method for manufacturing the circuit board of the present invention, the conductive member is formed by one of a printing method, a dispensing method, and a plating method.

The method for manufacturing the circuit board of the present invention further comprises: forming a second electrode electrically connected to the conductive member on the same surface as the solder resist.

According to the method for manufacturing the circuit board of the present invention, the second electrode is formed by one of the printing method, a drawing method, and an etching method.

According to a semiconductor device of the present invention, the conductive members included in the circuit board and solder bumps included in a semiconductor chip are bonded to each other via solder.

According to a semiconductor device of the present invention, the second electrodes included in the circuit board and solder bumps included in a semiconductor chip are bonded to each other via solder.

A method for manufacturing a semiconductor device of the present invention comprises: aligning the main electrodes included in the circuit board and the solder bumps included in the semiconductor chip and mounting the semiconductor chip on the circuit board, and melting the solder of the solder bumps and bonding the solder bumps and the conductive members included in the circuit board.

The method for manufacturing the semiconductor device of the present invention comprises: aligning the main electrodes included in the circuit board and the solder bumps included in the semiconductor chip and mounting the semiconductor chip on the circuit board, and melting the solder of the solder bumps and bonding the solder bumps and the second electrodes included in the circuit board.

According to the present invention, the conductive members electrically connected to the main electrodes of the circuit board are provided in the openings of the solder resist. Thus, by bonding the solder bumps of the semiconductor chip to the conductive members in the openings of the solder resist, an electrical connection can be easily obtained between the electrodes of the semiconductor chip and the main electrodes of the circuit board. Therefore, it is possible to improve the reliability of electrical connection between the semiconductor chip and the circuit board, increasing the yield of the semiconductor device.

Since the thickness (x) of the conductive member, the diameter (w) of the opening, the thickness (h) of the solder resist, and the radius (r) of the solder bump of the semiconductor chip satisfy h−r+{r²−(w/2)²}^{1/2}≦x, the conductive members and the solder bumps of the semiconductor chip are more easily brought into contact with each other. It is thus possible to further increase the yield of the semiconductor device.

Further, the second electrodes electrically connected to the conductive members formed in the openings of the solder resist are provided on the same surface of the solder resist. Thus, by bonding the solder bumps of the semiconductor chip to the second electrodes when the semiconductor chip is mounted, an electrical connection can be easily obtained between the electrodes of the semiconductor chip and the main electrodes of the circuit board. Further, it is only necessary to bond the solder bumps of the semiconductor chip to the second electrodes, and thus a large bump size can be set and a gap between the semiconductor chip and the circuit board can be increased, so that the filling property of underfil can be improved. Thus it is possible to achieve a semiconductor device with high yield and high connection reliability.

Since the second electrodes are provided, the openings of the solder resist can be set small in size, reducing the connection pads in size. Thus the wiring pitch can be reduced by reducing the connection pads in size, achieving high-density wiring. On the other hand, the wire can pass between the connection pads, the flexibility of wiring can be increased, and the routing density of wiring can be improved, thereby achieving high-density wiring. Since the openings of the solder resist can be set small in size, it is possible to reduce the demand for high position accuracy of the openings of the solder resist, so that the board can be manufactured with low cost and high yield.

Further, the second electrodes formed on the same surface of the solder resist are larger in diameter than the openings of the solder resist, and thus it is possible to increase a bonding area and a bonding strength to the solder bumps of the semiconductor chip, thereby improving the connection reliability of the semiconductor device. Particularly resistance to horizontal stress improves.

The partition wall having a larger thickness than the second electrode is provided between the second electrodes formed on the same surface as the surface of the solder resist. Thus the partition wall acts as a guide (guide portion) and can reduce a displacement when a semiconductor element is mounted. Moreover, it is possible to prevent the solder bumps from being crushed when solder is melted and prevent the occurrence of a solder bridge caused by a flow of molten solder, thereby increasing the yield of the semiconductor device. The partition wall covers the outer periphery of the second electrode, so that insulation reliability between the adjacent second electrodes can improves.

The conductive member preferably contains at least one material selected from the group consisting of gold (Au), silver (Ag), copper (Cu), tin (Sn), indium (In), lead (Pb), bismuth (Bi), zinc (Zn), nickel (Ni), antimony (Sb), platinum (Pt), and palladium (Pd). When selecting a material including at least one of these metals for the conductive member, it is possible to obtain a joint having a low resistance. Therefore, it is possible to make an excellent connection between the electrodes of the semiconductor chip and the main electrodes of the circuit board, thereby achieving a semiconductor device with high yield and high reliability.

The method for manufacturing the circuit board of the present invention makes it possible to manufacture a circuit board contributing to enhancement of yield. Further, the method for forming the conductive members in the openings of the solder resist is preferably one of the printing method, the dispensing method, and the plating method. These methods make it possible to manufacture the circuit board with low cost and high yield. The method for forming the second electrodes on the same surface as the solder resist is preferably one of the printing method, the drawing method, and the etching method. These methods make it possible to manufacture the circuit board with low cost and high yield.

According to the semiconductor device of the present invention and the method for manufacturing the same, it is possible to achieve a semiconductor device having a small size, a small thickness, and a high density with low cost and high yield.

### BRIEF DESCRIPTION OF THE DRAWINGS

FIG. 1 is a schematic diagram showing an example of a circuit board for flip-chip packaging according to Embodiment 1 of the present invention;

FIG. 2 is a schematic diagram for explaining an example of a manufacturing process of the circuit board for flip-chip packaging according to Embodiment 1 of the present invention;

FIG. 3 is a schematic sectional view showing an example of a circuit board for flip-chip packaging according to Embodiment 2 of the present invention;

FIG. 4 is a schematic diagram for explaining an example of a manufacturing process of the circuit board for flip-chip packaging according to Embodiment 2 of the present invention;

FIG. 5 is a schematic sectional view showing an example of a circuit board for flip-chip packaging according to Embodiment 3 of the present invention;

FIG. 6 is a schematic sectional view showing an example of a circuit board for flip-chip packaging according to Embodiment 4 of the present invention; and

FIG. 7 is a schematic sectional view showing an example of a circuit board for flip-chip packaging according to Embodiment 5 of the present invention.

### DESCRIPTION OF THE EMBODIMENTS

### Embodiment 1

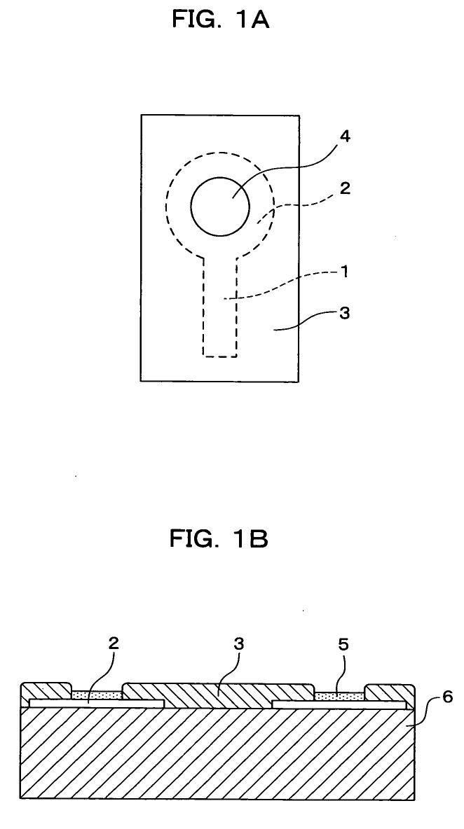

FIG. 1 is a schematic diagram showing an example of a circuit board for flip-chip packaging according to Embodiment 1 of the present invention. FIG. 1A is a partial enlarged plan view and FIG. 1B is a partial enlarged sectional view. In FIG. 1A, a solder resist and the opening of the solder resist are indicated by a solid line and a wiring pattern (wiring close to a connection pad) and the connection pad are indicated by a broken line.

In FIG. 1, reference numeral 1 denotes the wiring pattern, reference numeral 2 denotes the connection pad which is a main electrode of the circuit board, reference numeral 3 denotes the solder resist, reference numeral 4 denotes the opening formed on the connection pad 2, reference numeral 5 denotes a conductive member electrically connected to the connection pad 2, and reference numeral 6 denotes a substrate.

As shown in FIG. 1, the circuit board of Embodiment 1 includes the wiring patterns 1 and the connection pads 2 for flip-chip packaging on one surface of the substrate 6. Further, the circuit board includes the solder resist 3 which has the openings 4 on the connection pads 2 and covers the surface of the substrate 6 where the wiring patterns 1 and the connection pads 2 are formed. Moreover, the circuit board includes the conductive members 5 in the openings 4 of the solder resist 3.

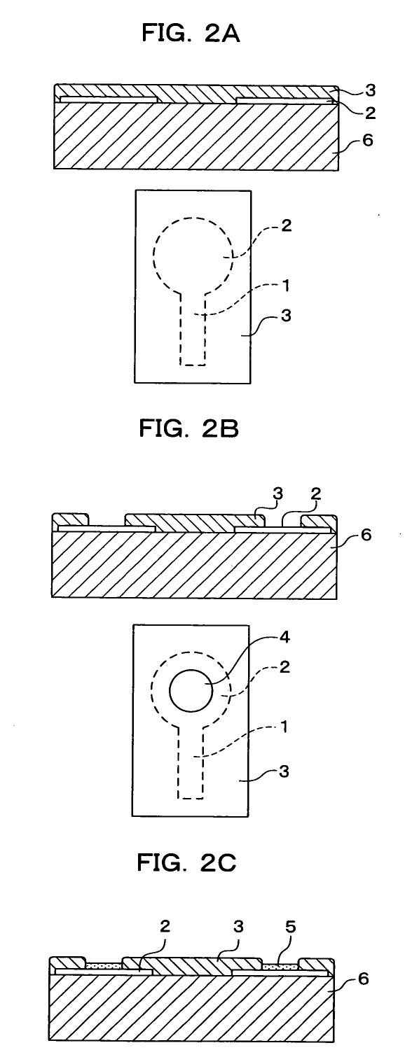

Referring to FIG. 2, an example of a method for manufacturing the circuit board will be described below. FIG. 2 is a schematic diagram for explaining an example of a manufacturing process of the circuit board for flip-chip packaging according to Embodiment 1 of the present invention. The upper drawings of FIGS. 2A and 2B are partial enlarged sectional views and the lower drawings of FIGS. 2A and 2B are partial enlarged plan views. FIG. 2C is a partial enlarged sectional view. In the lower drawings of FIGS. 2A and 2B, the solder resist and the opening of the solder resist are indicated by a solid line and the wiring pattern and the connection pad are indicated by a broken line.

First, as shown in FIG. 2A, the circuit board is prepared which includes the wiring patterns 1, the connection pads 2 for flip-chip packaging, and the solder resist 3 on one surface of the substrate 6. The solder resist 3 covers the surface of the substrate 6 where the wiring patterns 1 and the connection pads 2 are formed.

Next, as shown in FIG. 2B, the openings 4 of the solder resist 3 are formed on the connection pads 2 by the patterning method using exposure and development.

After that, as shown in FIG. 2C, the conductive members 5 are formed in the openings 4.

It is thus possible to obtain the circuit board for flip-chip packaging according to Embodiment 1.

In this case, the conductive member 5 is made of, for example, a material such as copper (Cu) having a high conductivity. Further, a method for forming the conductive members 5 in the openings 4 may be, for example, a printing method such as a screen printing method and a metal mask printing method, a dispensing method, and a plating method. By using these methods, it is possible to manufacture the circuit board for flip-chip packaging with low cost and high yield.

The following will describe a method for manufacturing a semiconductor device using the circuit board.

First, while the circuit board manufactured thus for flip-chip packaging is prepared, solder bumps are formed on pads which are the electrodes of a semiconductor chip.

Next, the semiconductor chip is flipped over and caused to face the circuit board, the solder bumps and the connection pads 2 of the circuit board are aligned with each other.

After that, the conductive members 5 and the solder bumps are brought into contact with each other and the semiconductor chip is mounted on the circuit board.

Next, heat is applied to melt the solder of the solder bumps, and the conductive members 5 and the solder bumps are bonded to each other via the solder, so that an electrical connection is obtained between the pads of the semiconductor chip and the connection pads of the circuit board.

Further, underfil is dispensed into a gap between the semiconductor chip and the circuit board and cured in the gap.

The semiconductor device manufactured thus has a small size, a small thickness, and a high density with low cost and high yield.

Since the conductive members 5 are formed thus in the openings 4, even when the opening 4 does not have a sufficient diameter relative to the size of the solder bump, the conductive member 5 and the solder bump can be brought into contact with each other, so that the electrodes of the semiconductor chip and the main electrodes of the circuit board can be electrically connected to each other.

In this case, the following relationship is satisfied:

h−r+{r²−(w/2)²}^{1/2}≦x

where x represents the thickness of the conductive member 5, w represents the diameter of the opening 4, h represents the thickness of the solder resist 3, and r represents the radius of the solder bump formed on the pad of the semiconductor chip. Thus, when the semiconductor chip is mounted, the conductive members 5 and the solder bumps of the semiconductor chip can be easily brought into contact with each other, achieving higher yield.

As a material of the conductive member 5, it is possible to use, for example, a material including at least one selected from the group consisting of gold (Au), silver (Ag), copper (Cu), tin (Sn), indium (In), lead (Pb), bismuth (Bi), zinc (Zn), nickel (Ni), antimony (Sb), platinum (Pt), and palladium (Pd). When selecting a material including at least one of these metals for the conductive member, it is possible to obtain a joint having a low resistance. Therefore, it is possible to make an excellent connection between the electrodes of the semiconductor chip and the main electrodes of the circuit board, thereby achieving a semiconductor device with high yield and high reliability.

According to Embodiment 1, even when the opening 4 does not have a sufficient diameter relative to the size of the solder bump, it is possible to easily obtain an electrical connection between the electrodes of the semiconductor chip and the main electrodes of the circuit board via the conductive members 5 formed in the openings 4. It is thus possible to improve the connection reliability of the semiconductor device, increasing the yield of the semiconductor device.

### Embodiment 2

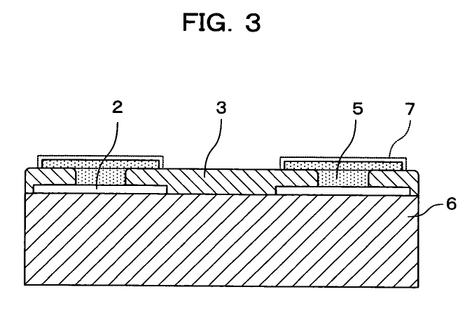

FIG. 3 is a schematic sectional drawing showing an example of a circuit board for flip-chip packaging according to Embodiment 2 of the present invention. The same members as those of Embodiment 1 are indicated by the same reference numerals and the explanation thereof is omitted.

In FIG. 3, members indicated by dotted lines 7 are second connection pads (second electrodes) for flip-chip packaging. As shown in FIG. 3, the feature of the circuit board for flip-chip packaging according to Embodiment 2 is the second connection pads 7 provided on the same surface as a solder resist 3. The connection pads 7 are electrically connected to conductive members 5 placed in openings 4.

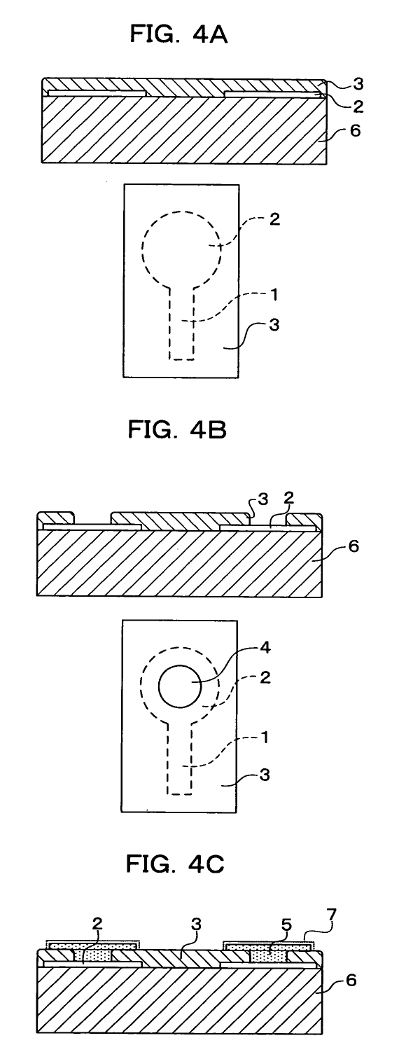

Referring to FIG. 4, an example of a method for manufacturing the circuit board will be described below. FIG. 4 is a schematic diagram for explaining an example of a manufacturing process of the circuit board for flip-chip packaging according to Embodiment 2 of the present invention. The upper drawings of FIGS. 4A and 4B are partial enlarged sectional views and the lower drawings of FIGS. 4A and 4B are partial enlarged plan views. FIG. 4C is a partial enlarged sectional view. In the lower drawings of FIGS. 4A and 4B, the solder resist and the opening of the solder resist are indicated by a solid line and a wiring pattern and the connection pad are indicated by a broken line.

First, as shown in FIG. 4A, the circuit board is prepared which includes a wiring pattern 1, first connection pads (main electrodes) 2 for flip-chip packaging, and the solder resist 3 on one surface of a substrate 6. The solder resist 3 covers the surface of the substrate 6 where the wiring pattern 1 and the connection pads 2 are formed.

Next, as shown in FIG. 4B, openings 4 of the solder resist 3 are formed on the connection pads 2 by a patterning method using exposure and development.

After that, as shown in FIG. 4C, the conductive members 5 are put and formed in the openings 4, and then the second connection pads 7 are formed by patterning on the same surface as the solder resist 3.

It is thus possible to obtain the circuit board for flip-chip packaging according to Embodiment 2.

A method for forming the second connection pads 7 by patterning may be, for example, a printing method such as a screen printing method and a metal mask printing method, a drawing method, an etching method, and so on. By using these methods, it is possible to manufacture the circuit board for flip-chip packaging with low cost and high yield.

The following will describe a method for manufacturing a semiconductor device using the circuit board.

First, while the circuit board manufactured thus for flip-chip packaging is prepared, solder bumps are formed on pads which are the electrodes of a semiconductor chip.

Next, the semiconductor chip is flipped over and is caused to face the circuit board, the solder bumps and the connection pads 2 of the circuit board are aligned with each other.

After that, the second connection pads 7 and the solder bumps are brought into contact with each other and the semiconductor chip is mounted on the circuit board.

Next, heat is applied to melt the solder of the solder bumps and the second connection pads 7 and the solder bumps are bonded to each other via the solder, so that an electrical connection is obtained between the pads of the semiconductor chip and the connection pads of the circuit board.

Further, underfil is dispensed into a gap between the semiconductor chip and the circuit board and cured in the gap.

The semiconductor device manufactured thus has a small size, a small thickness, and a high density and achieves low cost and high yield.

Since the second connection pads are provided thus, even when the opening 4 does not have a sufficient diameter relative to the size of the solder bump, the second connection pads and the solder bumps can be brought into contact with each other, so that the electrodes of the semiconductor chip and the main electrodes of the circuit board can be electrically connected to each other.

In this case, the relationship between the diameter of the second connection pad 7 and the diameter of the opening 4 is not particularly limited as long as the second connection pad 7 and the solder bump can be brought into contact with each other when the semiconductor chip is mounted. It is desirable that the second connection pad 7 be larger in diameter than the opening 4 because the second connection pad 7 and the solder bump can be easily brought into contact with each other. This configuration can increase a bonding area and a bonding strength to the solder bumps, thereby improving the connection reliability. Particularly resistance to horizontal stress improves.

According to Embodiment 2, even when the opening 4 does not have a sufficient diameter relative to the size of the solder bump, it is possible to easily obtain an electrical connection between the electrode of the semiconductor chip and the main electrode of the circuit board via the second electrode 7 and the conductive member 5 formed in the opening 4. Therefore, it is possible to obtain a semiconductor device with high yield.

Further, it is only necessary to bond the solder bumps of the semiconductor chip to the second electrodes, and thus a large bump size can be set and the gap between the semiconductor chip and the circuit board can be increased, so that the filling property of underfil can be improved. It is thus possible to achieve a semiconductor device with high yield and high connection reliability.

Moreover, since the openings of the solder resist can be set small in size, it is possible to reduce the demand for high position accuracy of the openings of the solder resist, so that the board can be manufactured with low cost and high yield.

### Embodiment 3

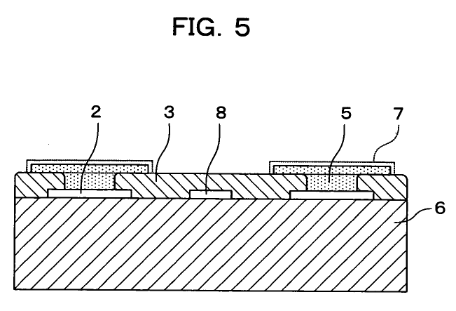

FIG. 5 is a schematic sectional view showing an example of a circuit board for flip-chip packaging according to Embodiment 3 of the present invention. The same members as those of Embodiments 1 and 2 are indicated by the same reference numerals and the explanation thereof is omitted.

In FIG. 5, reference numeral 8 denotes pattern wiring (connecting to a wiring pattern 1 and routing the wiring pattern 1 on a surface of a substrate 6). As shown in FIG. 5, the feature of the circuit board for flip-chip packaging according to Embodiment 3 is that a first connection pad 2 is smaller in diameter than a second connection pad 7 and the pattern wiring 8 is formed between the connection pads 2.

As described above, the first connection pad 2 can be reduced in diameter by providing the second connection pad 7. It is thus possible to dispose the pattern wiring 8 between the first connection pads 2, increase the flexibility of wiring, and improve the routing density of wiring, thereby achieving high-density wiring. Since the first connection pad 2 can be reduced in diameter, it is also possible to reduce the wiring pitch, thereby achieving high-density wiring.

### Embodiment 4

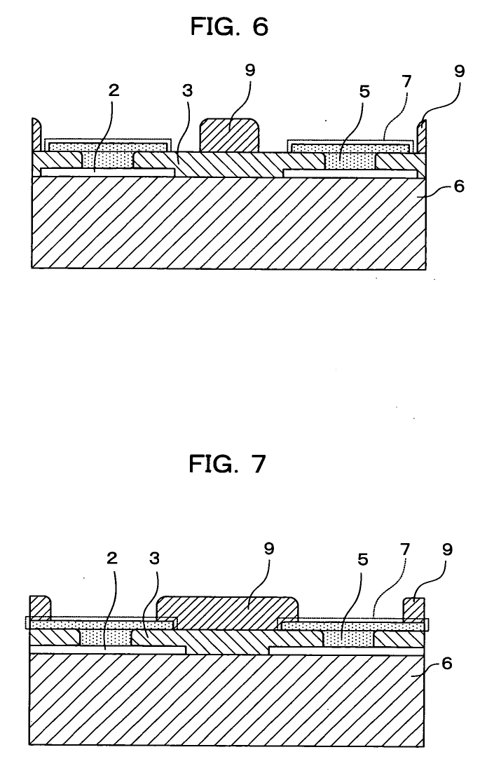

FIG. 6 is a schematic sectional view showing an example of a circuit board for flip-chip packaging according to Embodiment 4 of the present invention. The same members as those of Embodiments 1 and 2 are indicated by the same reference numerals and the explanation thereof is omitted.

In FIG. 6, reference numeral 9 denotes a partition wall. As shown in FIG. 6, the feature of the circuit board for flip-chip packaging according to Embodiment 4 is that the partition wall 9 having a larger thickness than a second connection pad 7 is provided between the second connection pads 7.

Since the partition wall 9 is provided thus, the partition wall acts as a guide (guide portion) and can reduce a displacement when a semiconductor element is mounted. Further, it is possible to prevent solder bumps from being crushed when solder is melted and prevent the occurrence of a solder bridge caused by a flow of molten solder, thereby achieving a semiconductor device with high yield. The partition wall has to be made of at least an insulating material. A method for forming the partition wall may be, for example, a printing method, a dispensing method, a drawing method, photolithography, and so on.

### Embodiment 5

FIG. 7 is a schematic sectional view showing an example of a circuit board for flip-chip packaging according to Embodiment 5 of the present invention. The same members as those of Embodiments 1, 2 and 4 are indicated by the same reference numerals and the explanation thereof is omitted.

As shown in FIG. 7, unlike Embodiment 4, the feature of Embodiment 5 is that a partition wall 9 is formed so as to cover the outer periphery of a second connection pad 7. The outer periphery of the second connection pad 7 is not always covered entirely with the partition wall 9.

By covering the outer periphery of the second connection pad 7 with the partition wall 9 in the above manner, insulation reliability between the adjacent second connection pads improves, thereby achieving a circuit board for flip-chip packaging with high reliability.

Experimental results of Embodiments 1 and 2 will be described below respectively as Example 1 and Example 2.

### EXAMPLE 1

In Example 1, a chip was used as a TEG (Test Element Group) for evaluation. The chip had a size of 10 mm×10 mm and a thickness of 300 μm and included 900 electrodes formed with a 250-μm pitch in an area array. A Sn—Ag solder bump having a radius of 55 μm was formed on an electrode (pad) of the TEG for evaluation.

On the other hand, as a circuit board, an ordinary glass epoxy double-sided copper clad laminate (“MCL-E-67”, Hitachi Chemical Co., Ltd., 1.6 mm in thickness) was prepared and wiring (wiring pattern and pattern wiring) and connection pads (main electrodes) were formed on the surface layer of the double-sided copper clad laminate with a pitch of 250 μm and a diameter of 200 μmφ by patterning using photolithography. At this point, the pattern of the wiring and connection pads was formed so as to make a daisy chain between the electrodes on the TEG for evaluation and the electrodes on the circuit board, so that a bonding property could be evaluated when a semiconductor is mounted.

Next, on the surface layer of the circuit board where the wiring and connection pads had been formed by patterning, a photoresist type solder resist (“PSR-4000”, TAIYO INK MFG. CO., LTD.) was formed. After that, the openings of the solder resist were formed with a predetermined size on the connection pads by exposure and development. The solder resist had a thickness of 25 μm. Further, the overlap of the diameter of the opening was set at 50 μm and four conditions of 40, 60, 80 and 100 μmφ were provided.

After that, silver paste (“NANOPASTE,” Vacuum Metallurgical CO., LTD. (now known as ULVAC Materials, Inc.)) was caused to adhere into the openings of the solder resist by a printing method, and was fired at 230° C. for one hour. At this point, for the thickness of a silver film which is a conductive member obtained after firing, five conditions of 5, 10, 15, 20 and 25 μm were provided by adjusting the printing conditions.

The circuit board for flip-chip packaging was manufactured thus.

Next, flux (“WHP-002”, Arakawa Chemical Industries, Ltd.) was transferred to the solder bumps formed on the pads (electrodes) of the TEG for evaluation. After that, the chip was mounted on the opposed circuit board and packaged using a reflow profile (at the peak temperature of 260° C./255° C. or higher for 10 to 20 seconds) recommended by NEMI (National Electronics Manufacturing Initiative) by means of a reflow furnace of infrared heating.

Thereafter, the flux was subjected to ultrasonic cleaning in a flux cleaner (“PINEALPHA ST-100SX”, Arakawa Chemical Industries, Ltd.) having been heated to 50° C., rinsed with pure water, and then dried at 125° C. for two hours.

Next, underfil (“CHIPCOAT U8437-2”, NAMICS CORPORATION) was dispensed on a hot plate of 90° C. and heated at 165° C. for 60 minutes, so that the underfil was cured.

A flip-chip semiconductor device was obtained thus.

For the obtained flip-chip semiconductor device, the resistance of the daisy chain was measured in each of the conditions. A resistance used for decision was obtained by dividing a measurement value, including wiring, by the number of bumps. The decision was OK when the resistance per bump was 200 mΩ or lower, and the decision was NG when the resistance per bump was higher than 200 mΩ. The results are shown in Table 1.

### [Table 1]

TABLE 1

| | | DIAMETER OF | | | | |
|---|---|---|---|---|---|---|
| | | SOLDER RESIST | | | | |
| | | OPENING (μm) | | | | |
| | | 20 | 40 | 60 | 80 | 100 |
| THICKNESS OF | 0 | NG | NG | NG | NG | OK |
| CONDUCTIVE | 5 | NG | NG | NG | NG | OK |
| MATERIAL (μm) | 10 | NG | NG | NG | OK | OK |
| | 15 | NG | NG | NG | OK | OK |
| | 20 | NG | NG | OK | OK | OK |
| | 25 | OK | OK | OK | OK | OK |

According to the results of Table 1, under the conditions that the opening of the solder resist is smaller in diameter than the solder bump, the solder bump could not come into contact with the silver film (conductive member) in the opening when the TEG for evaluation (semiconductor chip) was mounted, so that the solder bump did not spread in a wet manner during reflow and the connection was opened. Further, the thicker silver formed in the opening of the solder resist, the higher probability of contact between the solder bump of the TEG for evaluation and the silver film in the opening, so that the yield increased. High yield was obtained particularly when the following relationship is satisfied:

h−r+{r²−(w/2)²}^{1/2}≦x

where x represents the thickness of the silver film, w represents the diameter of the opening, h represents the thickness of the solder resist, and r represents the radius of the solder bump.

### EXAMPLE 2

In Embodiment 2, the same semiconductor chip as that of Embodiment 1 was used. Further, the same circuit board and solder resist as those of Embodiment 1 were used in Embodiment 2. Moreover, as in Embodiment 1, the diameter of the opening of the solder resist was set under the four conditions of 40, 60, 80 and 100 μmφ.

In Embodiment 2, after the openings of the solder resist were formed, a printing mask including openings having a diameter of 200 μmφ, which is larger than the opening of the solder resist, was placed on the solder resist. Further, silver paste (“NANOPASTE,” Vacuum Metallurgical CO., LTD. (now known as ULVAC Materials, Inc.)) was applied by a printing method through a screen mask and fired at 230° C. for one hour, so that a circuit board for flip-chip packaging was manufactured. Next, a semiconductor chip (TEG for evaluation) was mounted in the same manner as Embodiment 1. After a flux cleaning process and an underfil dispensing process, a flip-chip semiconductor device was obtained.

As in Embodiment 1, the resistance of a daisy chain was measured in each of the conditions for the obtained flip-chip semiconductor device. The criterion was set as in Embodiment 1. Table 2 shows the results. According to the results of Table 2, excellent connection could be obtained under any of the conditions.

### [Table 2]

TABLE 2

DIAMETER OF SOLDER
RESIST OPENING (μm)

| | 40 | 60 | 80 | 100 |
|---|---|---|---|---|
| DECISION | OK | OK | OK | OK |

The material of a conductive member is not limited to silver (Ag). It is possible to use a material including at least one selected from the group consisting of gold (Au), copper (Cu), tin (Sn), indium (In), lead (Pb), bismuth (Bi), zinc (Zn), nickel (Ni), antimony (Sb), platinum (Pt), and palladium (Pd).

A method for forming the conductive member is not limited to the printing method, and a dispensing method and a plating method can be used. Further, a method for forming second connection pads by patterning on the same surface as the solder resist is not limited to the printing method, and a drawing method and an etching method can be used.

According to the circuit board, the method for manufacturing the same, the semiconductor device, and the method for manufacturing the same of the present invention, the semiconductor device using a solder bonding method can have a small size, a small thickness, a high density, and high reliability. Thus the present invention is suitable for electronic equipment required to be small, lightweight, and thin.

What is claimed is:

1. A circuit board, comprising:
a substrate,
at least one wire formed on one surface of the substrate,
a plurality of main electrodes formed on the one surface of the substrate,
a solder resist covering the one surface of the substrate having the wire and the main electrodes formed thereon, the solder resist including openings on the main electrodes, and
a conductive member formed in the opening and electrically connected to the main electrode.

2. The circuit board according to claim 1, wherein h−r+{r²−(w/2)²}^{1/2}≦x is satisfied, where x represents a thickness of the conductive member, w represents a diameter of the opening, h represents a thickness of the solder resist, and r represents a radius of a solder bump formed on an electrode of a semiconductor chip mounted on the circuit board.

3. The circuit board according to claim 1, wherein the wire is disposed between the main electrodes.

4. The circuit board according to any one of claims 1 to 3, wherein the conductive member contains at least one material selected from the group consisting of gold, silver, copper, tin, indium, lead, bismuth, zinc, nickel, antimony, platinum, and palladium.

5. The circuit board according to claim 1, further comprising a second electrode electrically connected to the conductive member on the same surface as the solder resist.

6. The circuit board according to claim 5, wherein the second electrode is larger in diameter than the opening.

7. The circuit board according to claim 5, wherein the second electrode is larger in diameter than the main electrode.

8. The circuit board according to claim 5, further comprising a partition wall between the second electrodes, the partition wall being larger in thickness than the second electrode.

9. The circuit board according to claim 8, wherein the partition wall covers an outer periphery of the second electrode.

10. A method for manufacturing a circuit board, comprising:
preparing a circuit board including, on one surface of a substrate, at least one wire, a plurality of main electrodes, and a solder resist covering the one surface of the substrate having the wire and the main electrodes formed thereon,
forming openings of the solder resist on the main electrodes, and
forming a conductive member in each of the openings.

11. The method for manufacturing the circuit board according to claim 10, wherein the conductive member is formed by one of a printing method, a dispensing method, and a plating method.

12. The method for manufacturing the circuit board according to claim 10, further comprising: forming a second electrode electrically connected to the conductive member on the same surface as the solder resist.

13. The method for manufacturing the circuit board according to claim 12, wherein the second electrode is formed by one of a printing method, a drawing method, and an etching method.

14. A semiconductor device, comprising:
the circuit board according to claim 1, and
a semiconductor chip including a plurality of electrodes and solder bumps formed on the electrodes,
wherein the conductive members included in the circuit board and the solder bumps included in the semiconductor chip are bonded to each other via solder.

15. A semiconductor device, comprising:
the circuit board according to claim 5, and
a semiconductor chip including a plurality of electrodes and solder bumps formed on the electrodes,
wherein the second electrodes included in the circuit board and the solder bumps included in the semiconductor chip are bonded to each other via solder.

16. A method for manufacturing the semiconductor device according to claim 14, comprising:
aligning the main electrodes included in the circuit board and the solder bumps included in the semiconductor chip and mounting the semiconductor chip on the circuit board, and
melting the solder of the solder bumps and bonding the solder bumps and the conductive members included in the circuit board.

17. A method for manufacturing the semiconductor device according to claim 15, comprising:
aligning the main electrodes included in the circuit board and the solder bumps included in the semiconductor chip and mounting the semiconductor chip on the circuit board, and
melting the solder of the solder bumps and bonding the solder bumps and the second electrodes included in the circuit board.
